(19) United States
(12) Patent Application Publication
(10) Pub. No.: US 2026/0262430 A1
(43) Pub. Date: Sep. 3, 2026

(54) DISPLAY MODULE AND ELECTRONIC DEVICE

(71) Applicants: Chongqing BOE Display Technology Co., Ltd., Chongqing (CN); BOE TECHNOLOGY GROUP CO., LTD., Beijing (CN)

(72) Inventors: Yunhui Huang, Beijing (CN); Xiaoxia Huang, Beijing (CN); Chuanyong Li, Beijing (CN); Hao Sun, Beijing (CN); Ajuan Du, Beijing (CN); Wei Chen, Beijing (CN); Mengliang Yao, Beijing (CN); Yongle Wang, Beijing (CN); Yilun Zeng, Beijing (CN); Yiqian Wu, Beijing (CN); Guodong Zeng, Beijing (CN); Enjian Yang, Beijing (CN); Hufei Yang, Beijing (CN)

(73) Assignees: Chongqing BOE Display Technology Co., Ltd., Chongqing (CN); BOE TECHNOLOGY GROUP CO., LTD., Beijing (CN)

(21) Appl. No.: 18/993,093

(22) PCT Filed: May 20, 2024
(86) PCT No.: PCT/CN2024/094192

§ 371 Date: Jan. 10, 2025

(30) Foreign Application Priority Data
May 31, 2023 (CN) 202321371448.5

(51) Int. Cl. H10K 59/95; H10K 59/80

(52) U.S. Cl. CPC H10K 59/95; H10K 59/8794

(57) ABSTRACT

A display module and an electronic device are provided. The display module includes: a display panel, the display panel including a display member, a bending member and a binding member coupled in sequence, the bending member being bent so that the binding member is arranged at a side of a non-display surface of the display member; an FPC arranged on a binding surface of the binding member and electrically coupled to the display panel, the binding surface being a surface of the binding member distal to the display member; and a PCB arranged on the binding surface of the binding member, at least a portion of an orthogonal projection of the PCB being arranged in the binding member, and the PCB being electrically coupled to the FPC.

### CROSS-REFERENCE TO RELATED APPLICATION

This application claims a priority of the Chinese patent application No. 202321371448.5 filed on May 31, 2023, which is incorporated herein by reference in its entirety.

### TECHNICAL FIELD

The present disclosure relates to the field of display technology, in particular to a display module and an electronic device.

### BACKGROUND

Along with the rapid development of the display industry, a medium-and-small-sized Organic Light-Emitting Diode (OLED) display technology has gradually matured, and a medium-and-small-sized display product has been applied more and more widely. In the related art, considering the cost and a wiring design, for a medium-and-large-sized flexible OLED display product, usually an Electroluminescent Integrated Circuit (EL IC) is carried on a Printed Circuit Board (PCB). Through a Chip on Pi (COP) encapsulation technology, a very narrow lower bezel is provided. However, there is such a problem that the PCT needs to electrically coupled to a display panel via a Flexible Printed Circuit (FPC) and bonded to a non-display surface of the display panel. After the pad bending, a relatively large back space is occupied by the PCB and the FPC, so the spatial arrangement of the entire machine is adversely affected.

Hence, there is an urgent need to provide a new design scheme for a display module to at least solve the above-mentioned problem.

### SUMMARY

A main object of the present disclosure is to provide a display module and an electronic device, so as to reduce the back space of the display panel occupied by the PCB and the FPC.

In one aspect, the present disclosure provides in some embodiments a display module, including: a display panel, the display panel including a display member, a bending member and a binding member coupled in sequence, the bending member being bent so that the binding member is arranged at a side of a non-display surface of the display member; an FPC arranged on a binding surface of the binding member and electrically coupled to the display panel, the binding surface being a surface of the binding member distal to the display member; and a PCB arranged on the binding surface of the binding member, at least a portion of an orthogonal projection of the PCB being arranged in the binding member, and the PCB being electrically coupled to the FPC.

In a possible embodiment of the present disclosure, a first side of a first surface of the FPC is fixedly and electrically coupled to a side of the binding surface of the binding member distal to the bending member, the first surface is a surface of the FPC facing the binding member, the first side is a side of the first surface proximate to the binding member, and the PCB is arranged at a position on the binding surface of the binding member more proximate to the bending member relative to the FPC.

In a possible embodiment of the present disclosure, the PCB is electrically coupled to a second side of a second surface of the FPC, the second surface is a surface of the FPC opposite to the first surface, and an orthogonal projection of the second side onto the FPC does not overlap with an orthogonal projection of the first side onto the FPC.

In a possible embodiment of the present disclosure, a third surface of the PCB is fixedly coupled to the binding surface of the binding member at a position on the binding surface of the binding member more proximate to the bending member relative to the FPC, a third side of a fourth surface of the PCB is electrically coupled to the second side of the second surface of the FPC, the third surface is a surface of the PCB facing the binding member, the fourth surface is a surface of the PCB distal to the binding member, and the third side is a side of the fourth surface proximate to the FPC.

In a possible embodiment of the present disclosure, the third side of the fourth surface of the PCB is fixedly and electrically coupled to the second side of the second surface of the FPC through bending the FPC.

In a possible embodiment of the present disclosure, an orthogonal projection of the third surface of the PCB onto the binding surface of the binding member does not go beyond an orthogonal projection of the fourth surface onto the binding surface of the binding member.

In a possible embodiment of the present disclosure, the PCB is fixedly coupled, through a first sub-surface, to the binding surface of the binding member at a position on the binding surface of the binding member more proximate to the bending member relative to the FPC, a fourth side of a second sub-surface of the PCB is electrically coupled to the second side of the second surface of the FPC, the first sub-surface is a surface portion of the PCB opposite to the binding surface of the binding member, the second sub-surface is a surface portion of the PCB opposite to the second surface of the FPC, the fourth side is a side of the second sub-surface distal to the bending member, and the surface portion of the PCB opposite to the binding surface of the binding member and the surface portion of the PCB opposite to the second surface of the FPC are both surfaces of the PCB facing the binding member.

In a possible embodiment of the present disclosure, a thickness of the PCB at the first sub-surface is greater than a thickness of the PCB at the second sub-surface, so that the first sub-surface of the PCB is fixedly coupled to the binding surface of the binding member.

In a possible embodiment of the present disclosure, the display module further includes a connection member arranged between the first sub-surface of the PCB and the binding surface of the binding member, and the connection member is configured to fixedly couple the first sub-surface of the PCB to the binding surface of the binding member.

In a possible embodiment of the present disclosure, the display module further incudes a first driving integrated circuit board arranged on the binding surface of the binding member and electrically coupled to the display panel, the PCB includes a hollowed-out region, and an orthogonal projection of the hollowed-out region onto the binding surface of the binding member coincides with an orthogonal projection of the first driving integrated circuit board onto the binding surface of the binding member.

In a possible embodiment of the present disclosure, the display module further includes a second driving integrated circuit board arranged on the binding surface of the binding member and electrically coupled to the display panel, the PCB includes a first sub-board and a second sub-board electrically coupled to the each other, and an orthogonal projection of the first sub-board onto the binding surface of the binding member and an orthogonal projection of the second sub-board onto the binding surface of the binding member do not overlap with an orthogonal projection of the second driving integrated circuit board onto the binding surface of the binding member.

In a possible embodiment of the present disclosure, the display module further includes a third driving integrated circuit board arranged on a surface of the PCB distal to the binding member and electrically coupled to the display panel.

In a possible embodiment of the present disclosure, the PCB further includes a groove opened in a direction away from the binding member and configured to receive the third driving integrated circuit board.

In a possible embodiment of the present disclosure, the display module further includes: a first back film arranged on the non-display surface of the display member; a heat dissipation structural layer arranged on a surface of the first back film distal to the display member; a second back film arranged on a surface of the binding member facing the display member; a support layer arranged between the heat dissipation structural layer and the second back film and configured to support a curvature radius of the bending member; a protection adhesive layer arranged on a surface of the bending member at a same side as a display surface; a polarizer arranged on the display surface of the display member; and a cover plate arranged on a surface of the polarizer distal to the display member and fixedly coupled to the polarizer through an adhesive layer.

In another aspect, the present disclosure provides in some embodiments an electronic device including the above-mentioned display module.

The PCB is arranged on the binding surface of the binding member distal to the display member, so it is able to effectively reduce a back space of the display panel occupied by the PCB and the FPC.

### BRIEF DESCRIPTION OF THE DRAWINGS

The following drawings are provided to facilitate the understanding of the present disclosure, and constitute a portion of the description. These drawings and the following embodiments are for illustrative purposes only, but shall not be construed as limiting the present disclosure. In these drawings,

FIG. 1 is a schematic view showing a conventional display module;

FIG. 2 is a side view of the display module in an unbending state in FIG. 1;

FIG. 3 is a side view of the display module in a bending state in FIG. 1;

FIG. 4 is a side view of a display module in an unbending state according to one embodiment of the present disclosure;

FIG. 5 is a side view of the display module bent for once according to one embodiment of the present disclosure;

FIG. 6 is a side view of the display module bent for twice according to one embodiment of the present disclosure;

FIG. 7 is a side view of the display module before bending according to one embodiment of the present disclosure; and

FIG. 8 is a side view of the display module after bending according to one embodiment of the present disclosure.

### REFERENCE SIGN LIST

1, 11, 21, PNL display panel
2, 12, 22, FPC flexible printed circuit
3, 13, 23, PCB printed circuit board
231 first sub-surface
232 second sub-surface
4, 14, 24, DIC first driving integrated circuit
B/F back film
5a, 15a, 25a first back film
5b, 15b, 25b second back film
6, 16, 26, SCF heat dissipation structural layer
7, 17,27 support layer
8, 18,28 protection adhesive layer
9, 19,29 anisotropic conductive adhesive
X1, A1, B1 display member
X2, A2, B2 bending member
X3, A3, B3 binding member

### DETAILED DESCRIPTION OF THE EMBODIMENTS

It should be appreciated that, in the case of no conflict, the embodiments of the present disclosure and the features in the embodiments of the present disclosure may be combined with each other. The present disclosure will be described hereinafter in details in conjunction with the embodiments and drawings.

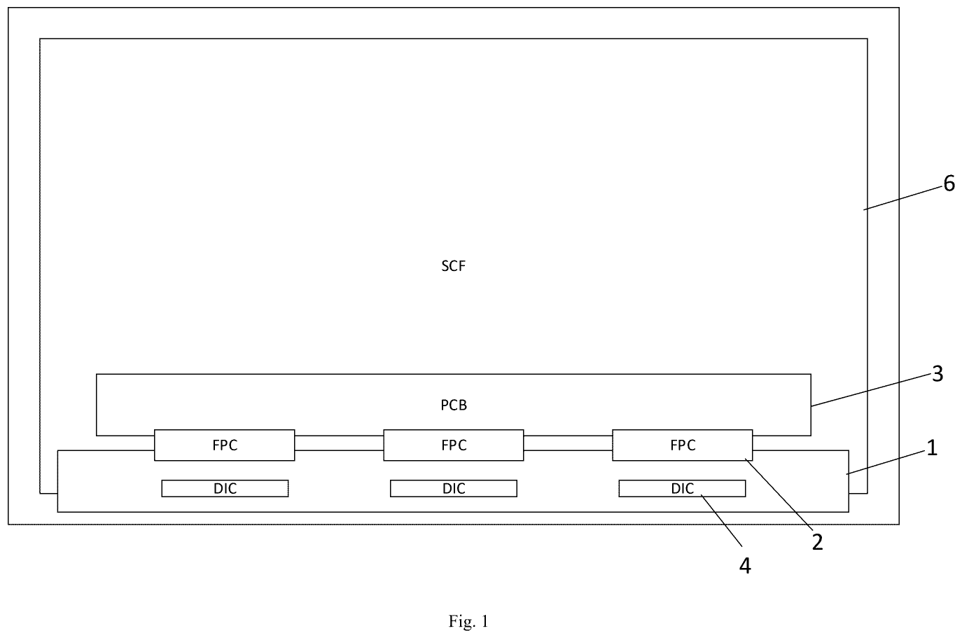

Referring to FIG. 1, in the related art, a display module includes a plurality of DICs and a plurality of FPCs to control pixel units in different regions of a display panel. The plurality of FPCs is electrically coupled to a PCB.

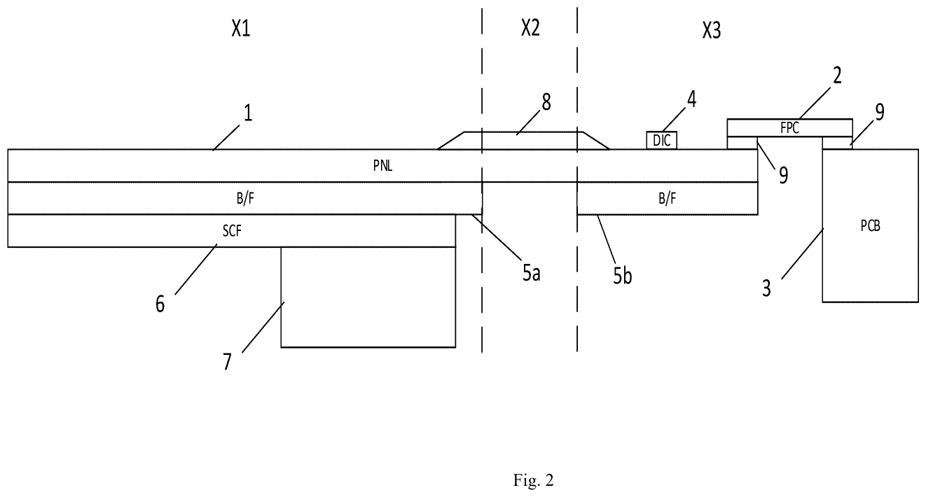

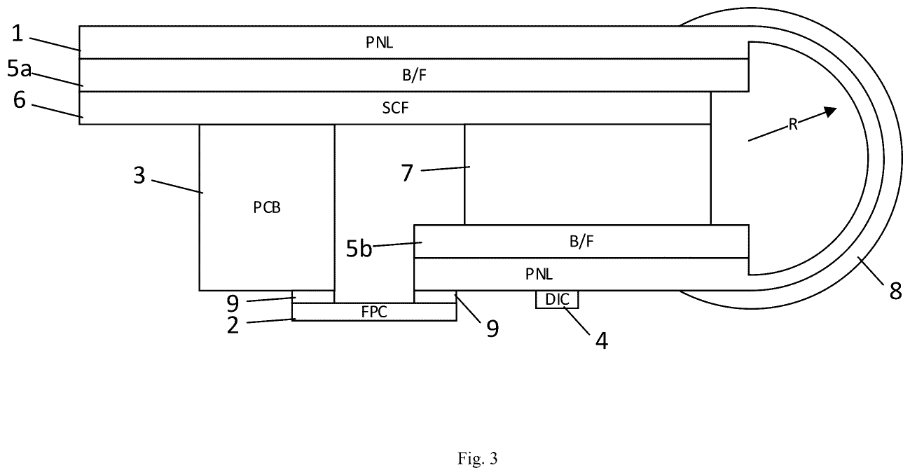

In the related art, the display module includes a display panel 1. Referring to FIG. 2, the display panel 1 includes a display member X1, a bending member X2 and a binding member X3 coupled sequentially, and the bending member X2 is arranged between the binding member X3 and the display member X1. Referring to FIG. 3, through bending the bending member X2, the binding member X3 is located at a side of a non-display surface of the display member X1. Referring to FIG. 2 or 3, an FPC 2 is arranged on a binding surface of the binding member X3, and electrically coupled to the display panel 1 through an anisotropic conductive adhesive 9. Referring to FIG. 3, the binding surface is a surface of the bending member X3 distal to the display member X1 after the bending member X2 is bent. Referring to FIG. 3, a PCB 3 is adhered to the non-display surface of the display member X1, and electrically coupled to the FPC 2 through the anisotropic conductive adhesive 9. A display surface of the display member X1 is a surface of the display panel at a light-exiting side, i.e., a surface at a side where light emitted by the pixel unit exits. The non-display surface of the display member X1 is a surface at a side of the display panel where no light exits, i.e., a surface opposite to the display surface.

Referring to FIGS. 1 to 3, the display module further includes a DIC 4 arranged on the binding surface of the binding member X3.

Referring to FIG. 3, the display module further includes: a first back film 5a arranged on the non-display surface of the display member X1; a second back film 5b arranged on a surface of the binding member X3 facing the display member; a heat dissipation structural layer 6 arranged on a surface of the first back film 5a away from the display member X1; a support layer 7 arranged between the heat dissipation structural layer 6 and the second back film 5b and configured to support a curvature radius R of the bending member X2; and a protection adhesive layer 8 arranged on a surface of the bending member X2 at a same side of the display surface as shown in FIG. 2.

In a case that a surface of the PCB where an active element is located faces a direction away from the display panel, at least a part of the surface is adhered to the FPC. After bending, the PCB is attached onto a Super Clear Foam (SCF). Both the PCB and the FPC occupy a back space of the display panel 1. For example, in a case that a width of the PCB is 12 mm and a width of the FPC is 6 mm, a back space of the display panel 1 having a width of 18 mm is occupied by the PCB and the FPC totally. At this time, a large space is occupied, and the arrangement of a battery and the other components may be adversely affected. In addition, an EL IC is arranged on the PCB, and a large current flows through the EL IC to generate heat obviously, so a temperature is relatively high (a measured temperature is 65° C.). Hence, the display panel easily displays a yellowish image at a corresponding position, and a service life of the display panel is reduced.

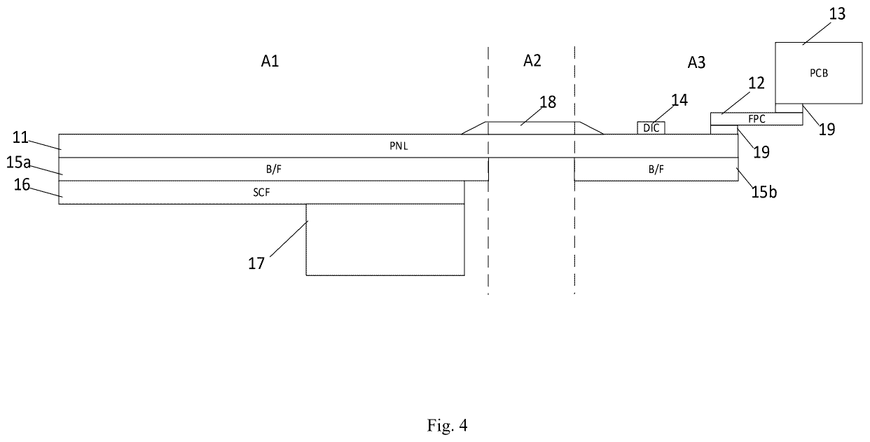

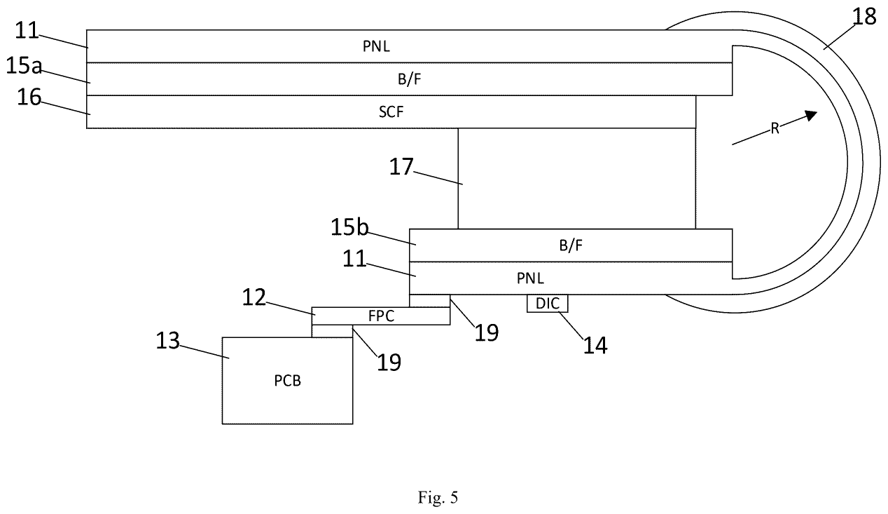

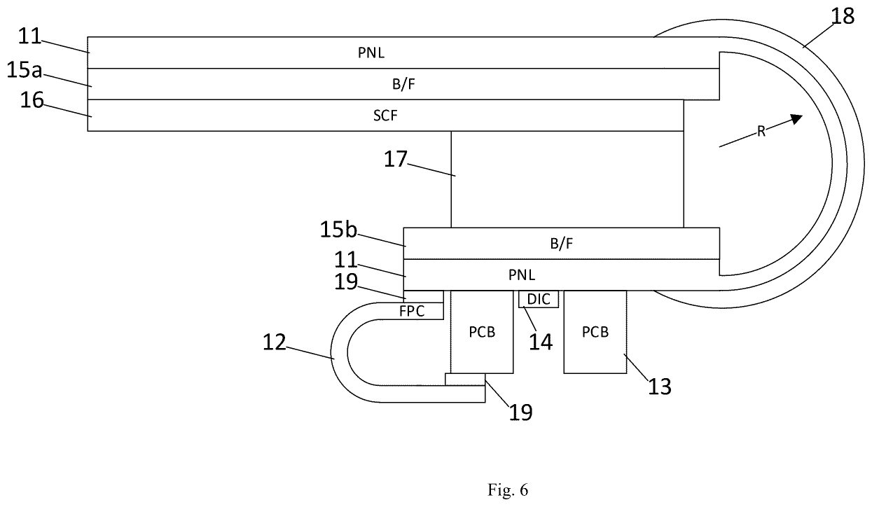

The present disclosure provides in some embodiments a display module, which includes a display panel 11, an FPC 12, and a PCB 13. Referring to FIG. 4, the display panel 11 includes a display member A1, a bending member A2 and a binding member A3 coupled sequentially. Referring to FIG. 5 or 6, through bending the bending member A2, the binding member A3 is arranged at a side of a non-display surface of the display member A1. Referring to FIGS. 4 to 6, the FPC12 is arranged on a binding surface of the binding member A3 and electrically coupled to the display panel 11. Referring to FIG. 5 or 6, the binding surface is a surface of the binding member A3 distal to the display member A1. Referring to FIG. 6, the PCB 13 is arranged on the binding surface of the binding member A3, at least a portion of an orthogonal projection of the PCB13 is arranged in the binding member A3, and the PCB13 is electrically coupled to the FPC12.

In the embodiments of the present disclosure, the PCB is arranged on the binding surface of the binding member distal to the display member, so as to effectively reduce a back space of the display panel occupied by the PCB and the FPC. For example, in a case that the PCB has a width of 12 mm and the FPC has a width of 6 mm, it is able to reduce a back space having a width of about 18 mm occupied by the PCB and the FPC. In addition, usually the PCB has a thickness of 0.7 mm, i.e., a thickness of the display module is increased by merely 1 mm (considering the PCB and an adhesive). Moreover, the PCB is separated from the display panel by the binding member and other possible film layers, so it is able to prevent heat generated by an ELIC on the PCB from being transferred to the display panel, and prevent the display panel from displaying a yellowish image, thereby to prolong a service life of the display panel, and remarkably reduce an influence caused by the heat generated by the EL IC on the display panel.

In a possible embodiment of the present disclosure, a first side of a first surface of the FPC 12 is fixedly and electrically coupled to a side of the binding surface of the binding member A3 distal to the bending member A2, the first surface is a surface of the FPC 12 facing the binding member A3, the first side is a side of the first surface proximate to the binding member A3, and the PCB 13 is arranged at a position on the binding surface of the binding member A3 more proximate to the bending member A2 relative to the FPC 12.

In the embodiments of the present disclosure, the PCB is arranged at a position on the binding surface of the binding member more proximate to the bending member relative to the FPC, so that the entire PCB is arranged on the binding surface of the binding member. In this way, it is able to effectively prevent the heat generated by the ELIC on the PCB from being transferred to the display panel, and prevent the display panel from displaying a yellowish image, thereby to prolong a service life of the display panel.

In some other embodiments of the present disclosure, the PCB may also be arranged at a position on the binding surface of the binding member more distal to the bending member relative to the FPC, or may be arranged at a position on the binding surface of the binding member spaced apart from the bending member by a same distance as the FPC. Relative positions of the PCB and the FPC on the binding surface of the binding member may be selected according to the practical needs, and thus will not be particularly defined herein.

In a possible embodiment of the present disclosure, the PCB 13 is electrically coupled to a second side of a second surface of the FPC 12, the second surface is a surface of the FPC 12 opposite to the first surface, and an orthogonal projection of the second side onto the FPC 12 does not overlap with an orthogonal projection of the first side onto the FPC 12.

In the embodiments of the present disclosure, the PCB and the binding surface of the binding member are electrically coupled to two opposite surfaces of the FPC respectively, so as to prevent the occurrence of the disordered arrangement of connection lines, thereby to facilitate the subsequent maintenance.

In some other embodiments of the present disclosure, the PCB and the binding surface of the binding member may also be electrically coupled to a same surface of the FPC according to the practical needs, which will not be particularly defined herein.

In a possible embodiment of the present disclosure, a third surface of the PCB 13 is fixedly coupled to the binding surface of the binding member A3 at a position on the binding surface of the binding member A3 more proximate to the bending member A2 relative to the FPC 12, a third side of a fourth surface of the PCB 13 is electrically coupled to the second side of the second surface of the FPC 12, the third surface is a surface of the PCB 13 facing the binding member A3, the fourth surface is a surface of the PCB 13 distal to the binding member A3, and the third side is a side of the fourth surface proximate to the FPC 12.

The PCB is fixedly coupled to the binding surface of the binding member through a pressure-sensitive adhesive. The PCB is electrically coupled to the FPC through a lead or an anisotropic conductive adhesive, and the FPC is electrically coupled to the display panel through a lead or an anisotropic conductive adhesive. For example, the anisotropic conductive adhesive is an Anisotropic Conductive Film (ACF) adhesive.

In the embodiments of the present disclosure, a surface of the PCB facing the binding member is fixedly coupled to the binding member, and a side of a surface of the PCB distal to the binding member and proximate to the FPC is electrically coupled to the FPC, so as to reduce a length of a lead through which the PCB is electrically coupled to the FPC.

In some other embodiments of the present disclosure, the other connection mode may also be adopted according to the practical needs, which will not be particularly defined herein.

In a possible embodiment of the present disclosure, the third side of the fourth surface of the PCB 13 is fixedly and electrically coupled to the second side of the second surface of the FPC 12 through bending the FPC 12.

In the embodiments of the present disclosure, through bending the FPC, the FPC is directly fixedly and electrically coupled to the PCB, so as to reduce a length of a lead through which the FPC is electrically coupled to the PCB.

In a possible embodiment of the present disclosure, an orthogonal projection of the third surface of the PCB 13 onto the binding surface of the binding member A3 does not go beyond an orthogonal projection of the fourth surface onto the binding surface of the binding member A3.

In the embodiments of the present disclosure, the PCB is adhered onto the binding surface of the binding member, without any necessity to provide the PCB with a special shape or thickness. In this way, it is able to reduce a back space of the display panel occupied by the PCB and the FPC, prevent the heat generated by the EL IC on the PCB from being transferred to the display panel, and prevent the display panel from displaying a yellowish image, thereby to prolong a service life of the display panel.

Referring to FIGS. 4 to 6, in order to obtain the display module in the embodiments of the present disclosure, a surface of the PCB where an active element is arranged is adhered to the FPC. After the display panel is bent, the surface of the PCB where the active element is arranged faces the display panel, and the FPC is bent again so that a surface of the PCB where no active element is arranged is adhered onto the binding surface of the binding member.

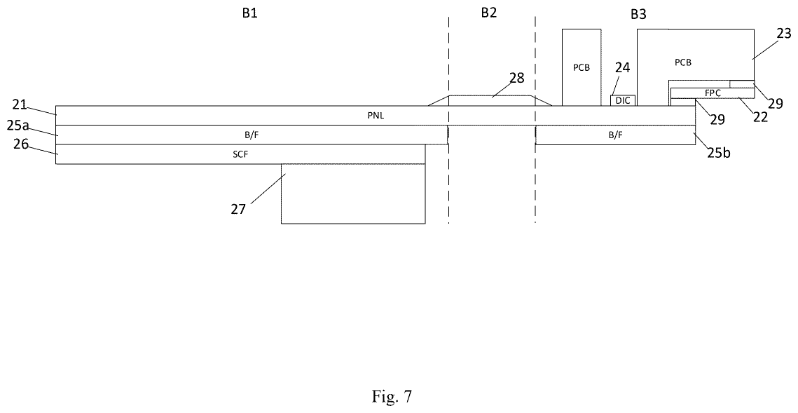

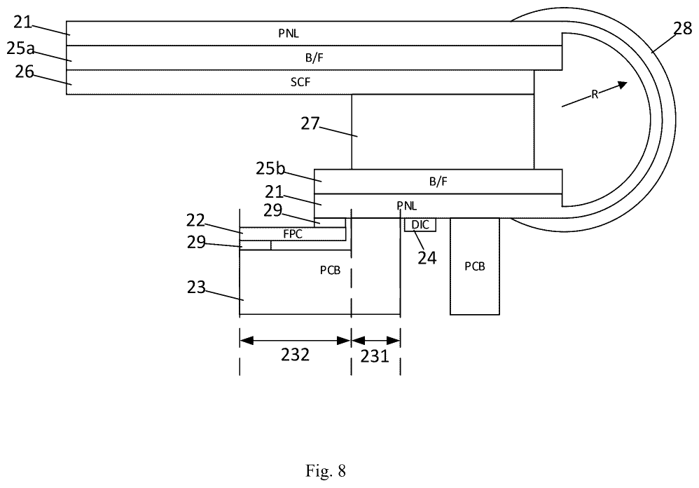

The present disclosure provides in some embodiments a display module, which includes a display panel 21, an FPC 22 and a PCB 23. Referring to FIG. 7, the display panel includes a display member B1, a bending member B2 and a binding member B3 coupled sequentially. Referring to FIG. 8, through bending the bending member B2, the binding member B3 is arranged at a side of a non-display surface of the display member 21. The FPC 22 is arranged on a binding surface of the binding member B3, and electrically coupled to the display panel 21. The binding surface is a surface of the binding member B3 distal to the display member B1. The PCB 23 is arranged on the binding surface of the binding member B3, at least a portion of an orthogonal projection of the PCB 23 is arranged in the binding member A3, and the PCB 23 is electrically coupled to the FPC 22.

In a possible embodiment of the present disclosure, a first side of a first surface of the FPC 22 is fixedly and electrically coupled to a side of the binding surface of the binding member B3 distal to the bending member B2, the first surface is a surface of the FPC 22 facing the binding member B3, the first side is a side of the first surface proximate to the binding member B3, and the PCB 23 is arranged at a position on the binding surface of the binding member B3 more proximate to the bending member B2 relative to the FPC 23.

In a possible embodiment of the present disclosure, the PCB 23 is electrically coupled to a second side of a second surface of the FPC 22, the second surface is a surface of the FPC 22 opposite to the first surface, and an orthogonal projection of the second side onto the FPC 22 does not overlap with an orthogonal projection of the first side onto the FPC 22.

The display module in this embodiment of the present disclosure has a substantially same beneficial effect as that mentioned hereinabove, which will not be particularly defined herein.

In a possible embodiment of the present disclosure, the PCB 23 is fixedly coupled, through a first sub-surface 231, to the binding surface of the binding member B3 at a position on the binding surface of the binding member B3 more proximate to the bending member B2 relative to the FPC 22, a fourth side of a second sub-surface 232 of the PCB is electrically coupled to the second side of the second surface of the FPC 22, the first sub-surface 231 is a surface portion of the PCB 23 opposite to the binding surface of the binding member B3, the second sub-surface 232 is a surface portion of the PCB 23 opposite to the second surface of the FPC 22, the fourth side is a side of the second sub-surface 232 distal to the bending member B2, and the surface portion of the PCB opposite to the binding surface of the binding member and the surface portion of the PCB opposite to the second surface of the FPC are both surfaces of the PCB 23 facing the binding member B3.

In the embodiments of the present disclosure, the PCB is provided with a large area, i.e., it includes the surface portion opposite to the binding surface of the binding member and the surface portion opposite to the second surface of the FPC. In this way, it is able to fix the PCB onto the binding surface of the binding member and enable the PCB to be electrically coupled to the FPC simultaneously without bending the FPC, thereby to prevent the FPC from being damaged due to the bending, and improve a service life of the FPC.

In a possible embodiment of the present disclosure, a thickness of the PCB 23 at the first sub-surface 231 is greater than a thickness of the PCB at the second sub-surface 232, so that the first sub-surface 231 of the PCB 23 is fixedly coupled to the binding surface of the binding member B3.

In the embodiments of the present disclosure, the thickness of the PCB is measured in a direction perpendicular to the binding surface of the binding member B3. Referring to FIG. 8, through increasing the thickness of the PCB at the first sub-surface, it is able to directly fix the PCB onto the binding surface of the binding member through its own structure, and improve the connection reliability between the PCB and the binding member.

In a possible embodiment of the present disclosure, the display module further includes a connection member (not shown) arranged between the first sub-surface 231 of the PCB 23 and the binding surface of the binding member B3, and the connection member is configured to fixedly couple the first sub-surface 231 of the PCB 23 to the binding surface of the binding member B3.

A material of the connection member may be selected according to the practical need, e.g., polyimide, which will not be particularly defined herein.

In the embodiments of the present disclosure, through the connection member, the PCB may have an even thickness. In addition, it is able to flexibly set a distance between the PCB and the binding surface of the binding member, thereby to improve the design flexibility.

Referring to FIGS. 7 and 8, in order to obtain the display module in the embodiments of the present disclosure, a surface of the PCB where no active element is arranged is adhered to the binding surface of the binding member and the FPC, and pins are provided at two sides of the FPC. Through bending the display panel, the PCB is arranged on the binding surface of the binding member, so as to reduce a back space of the display panel occupied by the PCB.

On the basis of FIG. 6 or 8, in a possible embodiment of the present disclosure, the display module further includes a first driving integrated circuit board (14 in FIG. 6 or 24 in FIG. 8) arranged on the binding surface of the binding member A3 or B3 and electrically coupled to the display panel 11 or 21, the PCB 13 or 23 includes a hollowed-out region, and an orthogonal projection of the hollowed-out region onto the binding surface of the binding member A3 or B3 coincides with an orthogonal projection of the first driving integrated circuit board 14 or 24 onto the binding surface of the binding member A3 or B3.

In the embodiments of the present disclosure, the first driving integrated circuit board is arranged on the binding surface of the binding member, and the PCB is hollowed out, so as to facilitate the heat dissipation of the first driving integrated circuit board, thereby to prevent the circuit board from being aged too early.

In another possible embodiment of the present disclosure, referring to FIG. 6 (the first driving integrated circuit board 14) or FIG. 8 (the first driving integrated circuit board 24), the PCB is directly perforated to form the hollowed-out region, so as to expose the first driving integrated circuit board, thereby to facilitate the heat dissipation.

On the basis of FIG. 6 or 8, in a possible embodiment of the present disclosure, the display module further includes a second driving integrated circuit board arranged on the binding surface of the binding member and electrically coupled to the display panel, the PCB includes a first sub-board (not shown) and a second sub-board (not shown) electrically coupled to the each other, and an orthogonal projection of the first sub-board onto the binding surface of the binding member and an orthogonal projection of the second sub-board onto the binding surface of the binding member do not overlap with an orthogonal projection of the second driving integrated circuit board onto the binding surface of the binding member.

In the embodiments of the present disclosure, the PCB is directly divided, so as to avoid the second driving integrated circuit board on the binding surface of the binding member, thereby to ensure a heat dissipation effect of the second driving integrated circuit board.

The PCB may be divided in a direction in which the PCB is coupled to the FPC, or divided in a direction angled relative to the direction in which the PCB is coupled to the FPC. The PCB may be divided into two sub-boards, or three or more sub-boards. The sub-boards may be coupled to each other through a lead, so as to operate as a whole. A specific dividing mode may be selected according to the practical need, which will not be particularly defined herein.

On the basis of FIG. 6 or 8, in a possible embodiment of the present disclosure, the display module further includes a third driving integrated circuit board arranged on a surface of the PCB distal to the binding member and electrically coupled to the display panel.

In the embodiments of the present disclosure, the third driving integrated circuit board is directly arranged on the surface of the PCB distal to the binding member, so as to completely expose the third driving integrated circuit board, thereby to facilitate the heat dissipation of the third driving integrated circuit board.

In another possible embodiment of the present disclosure, the PCB includes a groove opened in a direction away from the binding member and configured to receive the third driving integrated circuit board.

In the embodiments of the present disclosure, the third driving integrated circuit board is arranged in the groove in the PCB, so as to reduce a thickness of the display module, thereby to provide a thin screen.

The first, second and third driving integrated circuit boards may be arranged in a same display module or different display modules. The technical features may be split or combined by a person skilled in the art according to the practical need, which all fall within the scope of the present disclosure.

On the basis of FIGS. 4 to 8, in a possible embodiment of the present disclosure, the display module further includes: a first back film 15a, 25a arranged on the non-display surface of the display member; a heat dissipation structural layer 16, 26 arranged on a surface of the first back film 15a, 25a distal to the display member; a second back film 15b, 25b arranged on a surface of the binding member facing the display member; a support layer 17, 27 arranged between the heat dissipation structural layer 16, 26 and the second back film 15b, 25b and configured to support a curvature radius R of the bending member; a protection adhesive layer 18, 28 arranged on a surface of the bending member at a same side as a display surface; a polarizer (not shown) arranged on the display surface of the display member; and a cover plate (not shown) arranged on a surface of the polarizer distal to the display member and fixedly coupled to the polarizer through an adhesive layer (not shown).

The first back film 15a, 25a, the second back film 15b, 25b and the support layer 17, 27 are made of, e.g., polyethylene terephthalate (PET), or cyclic olefin polymer (COP). The heat dissipation structural layer 16, 26 includes, e.g., an adhesive layer, a buffer layer and a heat dissipation layer. The buffer layer is made of foam, and the heat dissipation layer is made of metal. The protection adhesive layer 18, 28 includes, e.g., an ultraviolet (UV)-curable adhesive or a Micro Coating Layer (MCL).

In the embodiments of the present disclosure, the PCB is coupled to the SCF through a copper (Cu) layer in an IC over tape, so that the PCB is grounded.

The present disclosure further provides in some embodiments an electronic device which includes the above-mentioned display module.

In the embodiments of the present disclosure, the electronic device may be any display apparatus or a device including a display apparatus, which includes, but not limited to, mobile phone, personal digital assistant, portable computer, GPS, camera, water, digital advertising display, or projector.

It should be appreciated that, the terms used in the embodiments of the present disclosure are for illustrative purposes only, but shall not be construed as limiting the illustrative embodiments of the present disclosure. The word “include” and “including” used in the embodiments of the present disclosure intend to indicate that there are features, steps, operations, elements, components and/or a combination thereof.

It should be further appreciated that, such words as “first” and “second” involved in the embodiments of the present disclosure are used to differentiate similar objects from each other, rather than describing a specific order, and they may be replaced with each other if appropriate.

It should be appreciated that, the illustrative embodiments of the present disclosure may be implemented in various forms but not limited to those mentioned hereinabove. Additionally, some steps may be omitted, or some steps may be combined, or one step may be divided into several sub-steps. The above embodiments are provided for better understanding of the present disclosure, but shall not be construed as limiting the scope of the present disclosure.

Although the spirit and principle of the present disclosure have been described hereinabove with reference to several specific embodiments, it should be appreciated that, the present disclosure is not limited to the disclosed specific embodiments. The division of the aspects also does not mean that the features in these aspects cannot be combined to gain some benefit, and this division is merely for ease of description. The present disclosure intends to cover all modifications and equivalents included in the spirit and scope defined by the appended claims.

1. A display module, comprising:
a display panel, the display panel comprising a display member, a bending member and a binding member coupled in sequence, wherein the binding member is arranged at a side of a non-display surface of the display member via bending of the bending member;
a Flexible Printed Circuit (FPC) arranged on a binding surface of the binding member and electrically coupled to the display panel, the binding surface being a surface of the binding member distal to the display member; and
a Printed Circuit Board (PCB) arranged on the binding surface of the binding member, at least a portion of an orthogonal projection of the PCB being arranged in the binding member, and the PCB being electrically coupled to the FPC.

2. The display module according to claim 1, wherein a first side of a first surface of the FPC is fixedly and electrically coupled to a side of the binding surface of the binding member distal to the bending member, the first surface is a surface of the FPC facing the binding member, the first side is a side of the first surface proximate to the binding member, and the PCB is arranged at a position on the binding surface of the binding member more proximate to the bending member relative to the FPC.

3. The display module according to claim 2, wherein the PCB is electrically coupled to a second side of a second surface of the FPC, the second surface is a surface of the FPC opposite to the first surface, and an orthogonal projection of the second side onto the FPC does not overlap with an orthogonal projection of the first side onto the FPC.

4. The display module according to claim 3, wherein a third surface of the PCB is fixedly coupled to the binding surface of the binding member at a position on the binding surface of the binding member more proximate to the bending member relative to the FPC, a third side of a fourth surface of the PCB is electrically coupled to the second side of the second surface of the FPC, the third surface is a surface of the PCB facing the binding member, the fourth surface is a surface of the PCB distal to the binding member, and the third side is a side of the fourth surface proximate to the FPC.

5. The display module according to claim 4, wherein the third side of the fourth surface of the PCB is fixedly and electrically coupled to the second side of the second surface of the FPC through bending the FPC.

6. The display module according to claim 4, wherein an orthogonal projection of the third surface of the PCB onto the binding surface of the binding member does not go beyond an orthogonal projection of the fourth surface onto the binding surface of the binding member.

7. The display module according to claim 3, wherein the PCB is fixedly coupled, through a first sub-surface of the PCB, to the binding surface of the binding member at a position on the binding surface of the binding member more proximate to the bending member relative to the FPC, a fourth side of a second sub-surface of the PCB is electrically coupled to the second side of the second surface of the FPC, the first sub-surface is a surface portion of the PCB opposite to the binding surface of the binding member, the second sub-surface is a surface portion of the PCB opposite to the second surface of the FPC, the fourth side is a side of the second sub-surface distal to the bending member, and the surface portion of the PCB opposite to the binding surface of the binding member and the surface portion of the PCB opposite to the second surface of the FPC are both surfaces of the PCB facing the binding member.

8. The display module according to claim 7, wherein a thickness of the PCB at the first sub-surface is greater than a thickness of the PCB at the second sub-surface, so that the first sub-surface of the PCB is fixedly coupled to the binding surface of the binding member.

9. The display module according to claim 7, further comprising a connection member arranged between the first sub-surface of the PCB and the binding surface of the binding member, wherein the connection member is configured to fixedly couple the first sub-surface of the PCB to the binding surface of the binding member.

10. The display module according to claim 1, further comprising a first driving integrated circuit board arranged on the binding surface of the binding member and electrically coupled to the display panel, wherein the PCB comprises a hollowed-out region, and an orthogonal projection of the hollowed-out region onto the binding surface of the binding member coincides with an orthogonal projection of the first driving integrated circuit board onto the binding surface of the binding member.

11. The display module according to claim 1, further comprising a second driving integrated circuit board arranged on the binding surface of the binding member and electrically coupled to the display panel, wherein the PCB comprises a first sub-board and a second sub-board electrically coupled to the each other, and an orthogonal projection of the first sub-board onto the binding surface of the binding member and an orthogonal projection of the second sub-board onto the binding surface of the binding member do not overlap with an orthogonal projection of the second driving integrated circuit board onto the binding surface of the binding member.

12. The display module according to claim 1, further comprising a third driving integrated circuit board arranged on a surface of the PCB distal to the binding member and electrically coupled to the display panel.

13. The display module according to claim 12, wherein the PCB further comprises a groove opened in a direction away from the binding member and configured to receive the third driving integrated circuit board.

14. The display module according to claim 1, further comprising:
a first back film arranged on the non-display surface of the display member;
a heat dissipation structural layer arranged on a surface of the first back film distal to the display member;
a second back film arranged on a surface of the binding member facing the display member;
a support layer arranged between the heat dissipation structural layer and the second back film and configured to support a curvature radius of the bending member;
a protection adhesive layer arranged on a surface of the bending member at a same side as a display surface;
a polarizer arranged on the display surface of the display member; and
a cover plate arranged on a surface of the polarizer distal to the display member and fixedly coupled to the polarizer through an adhesive layer.

15. An electronic device, comprising a display module, wherein the display module comprises:
a display panel, the display panel comprising a display member, a bending member and a binding member coupled in sequence, wherein the binding member is arranged at a side of a non-display surface of the display member via bending of the bending member;
an FPC arranged on a binding surface of the binding member and electrically coupled to the display panel, the binding surface being a surface of the binding member distal to the display member; and
a PCB arranged on the binding surface of the binding member, at least a portion of an orthogonal projection of the PCB being arranged in the binding member, and the PCB being electrically coupled to the FPC.

16. The electronic device according to claim 15, wherein a first side of a first surface of the FPC is fixedly and electrically coupled to a side of the binding surface of the binding member distal to the bending member, the first surface is a surface of the FPC facing the binding member, the first side is a side of the first surface proximate to the binding member, and the PCB is arranged at a position on the binding surface of the binding member more proximate to the bending member relative to the FPC.

17. The electronic device according to claim 16, wherein the PCB is electrically coupled to a second side of a second surface of the FPC, the second surface is a surface of the FPC opposite to the first surface, and an orthogonal projection of the second side onto the FPC does not overlap with an orthogonal projection of the first side onto the FPC.

18. The electronic device according to claim 17, wherein a third surface of the PCB is fixedly coupled to the binding surface of the binding member at a position on the binding surface of the binding member more proximate to the bending member relative to the FPC, a third side of a fourth surface of the PCB is electrically coupled to the second side of the second surface of the FPC, the third surface is a surface of the PCB facing the binding member, the fourth surface is a surface of the PCB distal to the binding member, and the third side is a side of the fourth surface proximate to the FPC.

19. The electronic device according to claim 18, wherein the third side of the fourth surface of the PCB is fixedly and electrically coupled to the second side of the second surface of the FPC through bending the FPC.

20. The electronic device according to claim 18, wherein an orthogonal projection of the third surface of the PCB onto the binding surface of the binding member does not go beyond an orthogonal projection of the fourth surface onto the binding surface of the binding member.
